(19) United States
(12) Patent Application Publication
(10) Pub. No.: US 2025/0275418 A1
(43) Pub. Date: Aug. 28, 2025

(54) DISPLAY DEVICE AND ELECTRONIC DEVICE INCLUDING THE SAME

(71) Applicant: Samsung Display Co., Ltd., Yongin-si (KR)

(72) Inventors: Jueyoun Park, Yongin-si (KR); Wonseok Kim, Yongin-si (KR); Intae Son, Yongin-si (KR); Kangwoo Lee, Yongin-si (KR); Dasong Lee, Yongin-si (KR)

(73) Assignee: Samsung Display Co., Ltd., Yongin-si (KR)

(21) Appl. No.: 19/024,148

(22) Filed: Jan. 16, 2025

(30) Foreign Application Priority Data
Feb. 22, 2024 (KR) 10-2024-0026038

(51) Int. Cl. H10K 59/80; H10H 29/85

(52) U.S. Cl. CPC H10K 59/8722; H10H 29/85

(57) ABSTRACT

A display device includes a display panel, a cover window disposed above the display panel, and an adhesive member disposed between the display panel and the cover window, the adhesive member including a first adhesive layer and a second adhesive layer disposed between the first adhesive layer and the cover window, a storage modulus of the first adhesive layer is greater than a storage modulus of the second adhesive layer, and an indentation modulus of the first adhesive layer is in a range of about 0.7 MPa to about 15 MPa.

### CROSS-REFERENCE TO RELATED APPLICATION(S)

This application claims priority to and benefits of Korean Patent Application No. 10-2024-0026038 under 35 U.S.C. § 119, filed on Feb. 22, 2024, in the Korean Intellectual Property Office, the entire contents of which are incorporated herein by reference.

### BACKGROUND

### 1. Technical Field

One or more embodiments relate to a display device and an electronic device including the same, and, to a display device including an adhesive member.

### 2. Description of the Related Art

Recently, the usage of display devices has been diversified. As display devices have become thinner and more lightweight, the range of usage thereof is broadening. As the scope of use of display devices diversifies, various methods for designing display devices of various shapes have been studied.

An adhesive member such as an optically clear adhesive is used to attach components of a display device to each other. The adhesive member provided in the display device is required to have excellent moisture resistance, heat resistance, and adhesion as well as optical properties.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

One or more embodiments include a display device having improved impact resistance and surface quality. However, the above objective is an example, and the scope of the disclosure is not limited by the above objective.

Additional aspects will be set forth in part in the description which follows and, in part, will be apparent from the description, or may be learned by practice of the presented embodiments of the disclosure.

According to one or more embodiments, a display device may include a display panel; a cover window disposed above the display panel, and an adhesive member disposed between the display panel and the cover window, the adhesive member including a first adhesive layer and a second adhesive layer disposed between the first adhesive layer and the cover window, wherein a storage modulus of the first adhesive layer is greater than a storage modulus of the second adhesive layer, and an indentation modulus of the first adhesive layer is in a range of about 0.7 MPa to about 15 MPa.

In an embodiment, the storage modulus of the second adhesive layer may be in a range of about 0.001 MPa to about 5 MPa at about-20° C. or lower.

In an embodiment, the storage modulus of the second adhesive layer may be in a range of about 0.001 MPa to about 8 MPa in a high frequency range of about 1,000 Hz to about 10,000 Hz.

In an embodiment, the storage modulus of the first adhesive layer may be in a range of about 0.5 MPa to about 1.5 MPa at about 25° C.

In an embodiment, the storage modulus of the second adhesive layer may be in a range of about 0.02 MPa to about 0.5 MPa at about 25° C.

In an embodiment, a thickness of the first adhesive layer may be less than a thickness of the second adhesive layer.

In an embodiment, the thickness of the first adhesive layer may be in a range of about 25 μm to about 75 μm.

In an embodiment, the thickness of the second adhesive layer may be in a range of about 75 μm to about 100 μm.

In an embodiment, the first adhesive layer may include an acrylic adhesive, an acrylate-based adhesive, a urethane acrylate-based adhesive, or a rubber adhesive.

In an embodiment, the second adhesive layer may include a urethane-based adhesive, an acrylic adhesive, or a urethane acrylate-based adhesive.

In an embodiment, the display device may further include a protection member disposed below the display panel.

According to one or more embodiments, a display device may include a display panel; a cover window disposed above the display panel, and an adhesive member disposed between the display panel and the cover window, the adhesive member including a first adhesive layer and a second adhesive layer disposed between the first adhesive layer and the cover window, wherein a storage modulus of the first adhesive layer is greater than a storage modulus of the second adhesive layer, and the storage modulus of the second adhesive layer is in a range of about 0.001 MPa to about 5 MPa at about −20° C. or lower.

In an embodiment, the storage modulus of the second adhesive layer may be in a range of about 0.001 MPa to about 8 MPa in a high frequency range of about 1,000 Hz to about 10,000 Hz.

In an embodiment, the storage modulus of the first adhesive layer may be in a range of about 0.5 MPa to about 1.5 MPa at about 25° C.

In an embodiment, the storage modulus of the second adhesive layer may be in a range of about 0.02 MPa to about 0.5 MPa at about 25° C.

In an embodiment, a thickness of the first adhesive layer may be less than a thickness of the second adhesive layer.

In an embodiment, the thickness of the first adhesive layer may be in a range of about 25 μm to about 75 μm.

In an embodiment, the thickness of the second adhesive layer may be in a range of about 75 μm to about 100 μm.

In an embodiment, the first adhesive layer may include an acrylic adhesive, an acrylate-based adhesive, a urethane acrylate-based adhesive, or a rubber adhesive.

In an embodiment, the second adhesive layer may include a urethane-based adhesive, an acrylic adhesive, or a urethane acrylate-based adhesive.

According to one or more embodiments, an electronic device includes a display device, wherein the display device may include a display panel; a cover window disposed above the display panel, and an adhesive member disposed between the display panel and the cover window, the adhesive member including a first adhesive layer and a second adhesive layer disposed between the first adhesive layer and the cover window, wherein a storage modulus of the first adhesive layer is greater than a storage modulus of the second adhesive layer, and an indentation modulus of the first adhesive layer is in a range of about 0.7 MPa to about 15 MPa.

In an embodiment, the electronic device may further include a display module, a processor, a power module, and a memory, wherein the display device may include one of the display module, the processor, the power module, or the memory.

### BRIEF DESCRIPTION OF THE DRAWINGS

The above and other aspects, features, and advantages of embodiments will be more apparent from the following description taken in conjunction with the accompanying drawings, in which:

FIG. 1 is a schematic perspective view schematically illustrating a display device according to an embodiment;

FIG. 2 is a schematic cross-sectional view schematically illustrating a cross-section of the display device taken along line A-A′ in FIG. 1;

FIGS. 3A, 3B, and 3C are diagrams illustrating images of an embodiment and comparative examples;

FIG. 4 is a schematic plan view schematically illustrating a display panel included in a display device according to an embodiment;

FIG. 5 is a schematic diagram of an equivalent circuit of a pixel of a display panel and a display element connected to the pixel circuit;

FIG. 6 is a schematic cross-sectional view schematically illustrating a cross-section of the display panel of FIG. 4, taken along line B-B′ of FIG. 4; and

FIG. 7 is a block diagram of an electronic device according to an embodiment.

FIG. 8 is a schematic diagrams of electronic devices according to various embodiments.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are described below, by referring to the figures, to explain aspects of the description.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

As the disclosure allows for various changes and numerous embodiments, embodiments will be illustrated in the drawings and described in detail in the written description. The effects and features of the disclosure, and ways to achieve them will become apparent by referring to embodiments that will be described later in detail with reference to the drawings. However, the disclosure is not limited to the following embodiments but may be embodied in various forms.

In the specification, it will be understood that although the terms “first”, “second”, etc. may be used herein to describe various elements, these elements should not be limited by these terms. These terms are only used to distinguish one element from another.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

As used herein, the singular forms, “a,” “an,” and “the” are intended to include the plural forms as well, unless the context clearly indicates otherwise.

In the specification, the terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

Herein, “A and/or B” may indicate A, B, or both A and B. Also, “at least one of A and B” may indicate only A, only B, or both A and B.

In the specification, it will be understood when various elements such as a layer, a film, an area, or a plate is referred to as being “on” or “above” another element, it can be directly on or above the other element, or an intervening element may also be present.

In the specification, when layers, regions, or elements are described as being connected, other layers, this indicates a case where layers, regions, and elements are directly connected or/and a case where layers, regions, and elements are indirectly connected with other layers, regions, and elements therebetween. For example, herein, when layers, regions, or elements are described as being electrically connected, this indicates a case where layers, regions, and elements are directly electrically connected and/or a case where layers, regions, and elements are indirectly electrically connected with other layers, regions, and elements therebetween.

In the specification, an x-axis, a y-axis, and a z-axis are not limited to three axes on a rectangular coordinates system but may be construed as including these axes. For example, an-x axis, a y-axis, and a z-axis may be at right angles or may also indicate different directions from one another, which are not at right angles.

In this specification, “on a plane” means when a target portion is viewed from above. For example, in this specification, “on a plane” may mean “when viewed in a direction perpendicular to the substrate 100.”

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the disclosure will be described in detail with reference to the accompanying drawings, and in the description with reference to the drawings, like reference numerals refer to like elements and redundant descriptions thereof may be omitted. In the drawings, for convenience of description, sizes of elements may be exaggerated or contracted. For example, since sizes and thicknesses of elements in the drawings are arbitrarily illustrated for convenience of explanation, the following embodiments are not limited thereto.

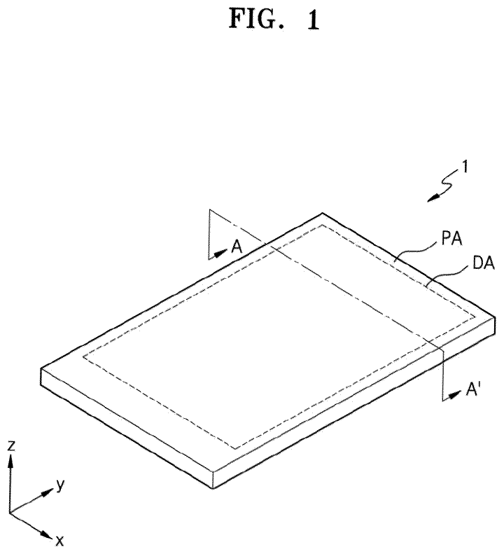

FIG. 1 is a schematic perspective view schematically illustrating a display device 1 according to an embodiment.

Referring to FIG. 1, the display device 1 may include a display area DA and a peripheral area PA surrounding the display area DA. The display device 1 may provide an image through an array of pixels arranged (or disposed) two-dimensionally in the display area DA. Each pixel of the display device 1 is an area that may emit light of a certain color, and the display device 1 may provide an image by using light emitted from the pixels. For example, each pixel may emit red, green, or blue light.

In an embodiment, the display area DA may have a polygonal shape including a quadrangle. For example, the display area DA may have a rectangular shape having a shorter width than a length thereof or a rectangular shape having a longer width than a length thereof, or a square shape. By way of example, the display area DA may have various shapes such as an oval or a circle.

The peripheral area PA is a non-display area from which no image is provided, and may entirely surround the display area DA. In the peripheral area PA, a driver or a main voltage line for providing an electrical signal or power to pixel circuits may be arranged. A pad which is an area, to which an electronic element or a printed circuit board may be electrically connected, may be arranged in the peripheral area PA.

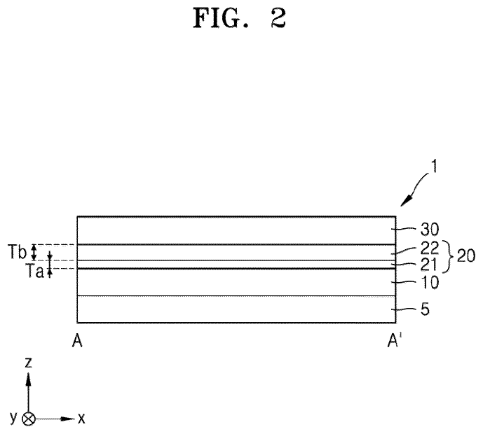

FIG. 2 is a schematic cross-sectional view of a cross-section of the display device 1 taken along line A-A′ of FIG. 1.

Referring to FIG. 2, the display device 1 may include a display panel 10, an adhesive member 20, and a cover window 30. In an embodiment, the display device 1 may further include a protection member 5.

The display panel 10 may display an image. In other words, an image provided by the display device 1 may be understood as being implemented by the display panel 10. The display panel 10 may include display elements, and the display elements may emit light. Accordingly, the display panel 10 may display images through light emitted from display elements.

The display element may be a light-emitting diode (LED). In an embodiment, the display element may be an organic light-emitting diode including an organic emission layer. By way of example, the display element may be a quantum dot LED including a quantum-dot emission layer. By way of example, the display element may be an inorganic LED including an inorganic semiconductor. In an embodiment, the size of the LED may be micro scale or nano scale. For example, the LED may be a micro LED. By way of example, the LED may be a nanorod LED. Nanorod LEDs may include gallium nitride (GaN). In an embodiment, a color conversion layer may be disposed on the nanorod LED. The color conversion layer may include quantum dots.

The cover window 30 may be disposed on the display panel 10. The cover window 30 may be disposed on an upper surface of the display panel 10. Here, the ‘upper surface’ of the display panel 10 may be defined as a surface facing a direction in which the display panel 10 provides an image. For example, the ‘upper surface’ of the display panel 10 may be a first surface facing a +z direction. In an embodiment, the cover window 30 may be arranged (or disposed) to cover the upper surface of the display panel 10. The cover window 30 may function to protect the upper surface of the display panel 10. The cover window 30 may include a flat surface and a curved surface corresponding to the shape of the display device 1.

The cover window 30 may have a high transmittance to transmit light emitted from the display panel 10 and may have a thin thickness to minimize the weight of the display device 1. The cover window 30 may have high strength and hardness to protect the display panel 10 from external shock. In an embodiment, the cover window 30 may be a flexible window. The cover window 30 may protect the display panel 10 by readily bending in response to external force without generating cracks or the like within the spirit and the scope of the disclosure.

In an embodiment, the cover window 30 may include glass, sapphire, or plastic. For example, the cover window 30 may be ultra-thin glass (UTG®) which has a strength reinforced by chemical reinforcement or thermal reinforcement, or may be transparent polyimide (colorless polyimide (CPI)). The cover window 30 may have a structure in which a flexible polymer layer is disposed on one side or a side of a glass substrate, or may include only a polymer layer. An image displayed by the display panel 10 may be provided to a user through the cover window 30 that is transparent.

The adhesive member 20 may be disposed between components of the display device 1 to attach one component of the display device 1 to another component. For example, the adhesive member 20 may be between the display panel 10 and the cover window 30. For example, the adhesive member 20 may be disposed on the display panel 10, and the cover window 30 may be disposed on the adhesive member 20. The adhesive member 20 may be used attach the cover window 30 to the display panel 10.

The adhesive member 20 may include at least two layers of adhesive layers having different storage moduli. For example, the adhesive member 20 may include a first adhesive layer 21 and a second adhesive layer 22 which have different storage moduli from each other, the second adhesive layer 22 being on the first adhesive layer 21.

The storage modulus of the first adhesive layer 21 may be greater than the storage modulus of the second adhesive layer 22. For example, at about 25° C., the storage modulus of the first adhesive layer 21 may be in a range of about 0.5 MPa to about 1.5 MPa. For example, at about 25° C., the storage modulus of the first adhesive layer 21 may be in a range of about 0.5 MPa to about 1 MPa. For example, at about 25° C., the storage modulus of the second adhesive layer 22 may be in a range of about 0.02 MPa to about 0.5 MPa. For example, at about 25° C., the storage modulus of the second adhesive layer 22 may be in a range of about 0.02 MPa to about 0.1 MPa. The first adhesive layer 21 may be referred to as a hard adhesive layer, and the second adhesive layer 22 may be referred to as a soft adhesive layer.

The first adhesive layer 21 may improve the surface quality of the display device 1 by preventing or reducing waviness of the display device 1, and the second adhesive layer 22 may improve the impact resistance of the display device 1. For example, as the adhesive member 20 may include the first adhesive layer 21 having a relatively large storage modulus and the second adhesive layer 22 having a relatively small storage modulus, the surface quality of the display device 1 may be improved and at the same time the impact resistance thereof may be improved.

In an embodiment, the first adhesive layer 21 may be disposed on the display panel 10, and the second adhesive layer 22 may be disposed on the first adhesive layer 21. The second adhesive layer 22 may be arranged between the first adhesive layer 21 and the cover window 30. The first adhesive layer 21 may be arranged between the display panel 10 and the second adhesive layer 22. The first adhesive layer 21 is an adhesive layer arranged relatively closer to the display panel 10 than the second adhesive layer 22, and may be referred to as a lower adhesive layer. The second adhesive layer 22 is a layer arranged relatively closer to the cover window 30 than the first adhesive layer 21, and may be referred to as an upper adhesive layer.

In an embodiment, a hard adhesive layer is disposed above the display panel 10, and a soft adhesive layer is disposed above the hard adhesive layer, so that the degree of improvement in surface quality and impact resistance of the display device 1 may be greater than that of a comparative example in which a soft adhesive layer is disposed above the display panel 10, and a hard adhesive layer is disposed above the soft adhesive layer.

A thickness Ta of the first adhesive layer 21 may be less than a thickness Tb of the second adhesive layer 22. For example, the thickness Ta of the first adhesive layer 21 may be in a range of about 25 μm to about 75 μm. If the thickness Ta of the first adhesive layer 21 exceeds 75 μm, impact resistance may decrease. If the thickness Ta of the first adhesive layer 21 is less than 25 μm, surface quality may decrease. For example, the thickness Tb of the second adhesive layer 22 may be in a range of about 75 μm to about 100 μm. If the thickness Tb of the second adhesive layer 22 exceeds about 100 μm, the surface quality may decrease due to the display panel 10 being pressed. If the thickness Tb of the second adhesive layer 22 is less than 75 μm, impact resistance may decrease. According to an embodiment, in case that the thickness Tb of the second adhesive layer 22, which is a soft adhesive layer, is relatively larger, the impact resistance may be improved compared to a comparative example in which the thickness Ta of the first adhesive layer 21, which is a hard adhesive layer, is relatively larger.

An indentation modulus Err of the first adhesive layer 21 may be in a range, for example, of about 0.7 MPa to about 15 MPa. An indentation modulus Err of the first adhesive layer 21 may be in a range, for example, of about 1 MPa to about 15 MPa. An indentation modulus Err of the first adhesive layer 21 may be in a range, for example, of about 1.2 MPa to about 15 MPa. The indentation modulus may be an elastic modulus measured using a nanoindenter. In case that the indentation modulus of the first adhesive layer 21 satisfies the above ranges, the display panel 10 may be prevented from being pressed by the protection member 5 including a cushion layer on the display panel 10. For example, in case that the indentation modulus of the first adhesive layer 21 satisfies the above ranges, waviness of the display panel 10 or the display device 1 may be prevented or reduced.

The storage modulus of the second adhesive layer 22 may be in a range, for example, of about 0.001 MPa to about 5 MPa at low temperatures. For example, at about −20° C. or lower, the storage modulus of the second adhesive layer 22 may be in a range of about 0.001 MPa to about 5 MPa. For example, at about −20° C. or lower, the storage modulus of the second adhesive layer 22 may be in a range of about 0.001 MPa to about 2 MPa. In case that the storage modulus of the second adhesive layer 22 satisfies the above range at low temperature, the impact resistance of the display panel 10 or the display device 1 may be improved.

The storage modulus of the second adhesive layer 22 may be in a range of about 0.001 MPa to about 8 MPa, for example, in a high frequency range of about 1000 Hz to about 10000 Hz. For example, the storage modulus of the second adhesive layer 22 may be in a range of about 0.001 MPa to about 3 MPa in a high frequency range of about 1000 Hz to about 10000 Hz. In case that the storage modulus of the second adhesive layer 22 satisfies the above ranges in the high frequency range, the impact resistance of the display panel 10 or the display device 1 may be improved. If the storage modulus of the second adhesive layer 22 exceeds 8 MPa in the high frequency range, impact resistance may be significantly reduced.

The first adhesive layer 21 and the second adhesive layer 22 may include an adhesive such as an optical clear adhesive (OCA) or a pressure sensitive adhesive (PSA). The first adhesive layer 21 may include an acrylic adhesive, an acrylate-based adhesive, a urethane acrylate-based adhesive, or a rubber adhesive. The second adhesive layer 22 may include a urethane-based adhesive, an acrylic adhesive, or a urethane acrylate-based adhesive.

The protection member 5 may be disposed under or below the display panel 10. The protection member 5 may be disposed on a lower surface of the display panel 10. Here, the ‘lower surface’ of the display panel 10 may be defined as a surface facing a direction opposite to the direction in which the display panel 10 provides an image. For example, the ‘lower surface’ of the display panel 10 may be a second surface facing a-z direction. In an embodiment, the protection member 5 may be arranged to cover the lower surface of the display panel 10. The protection member 5 may function to protect the lower surface of the display panel 10 by absorbing external impact. The protection member 5 may serve to attach the display panel 10 to other components such as a case, without damage. The protective member 5 may include a cushion layer. The cushion layer may be, for example, a porous cushion layer such as polymer resin foam.

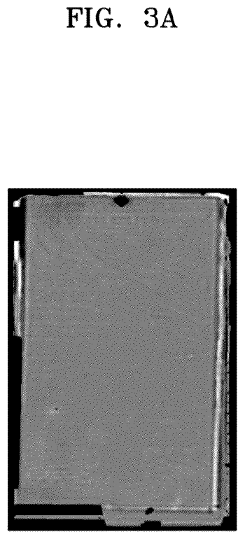

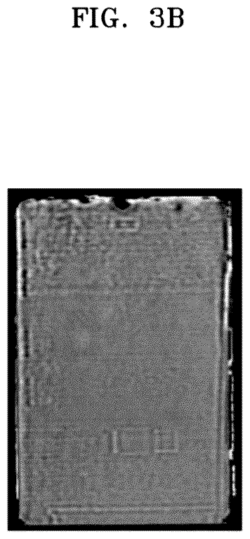

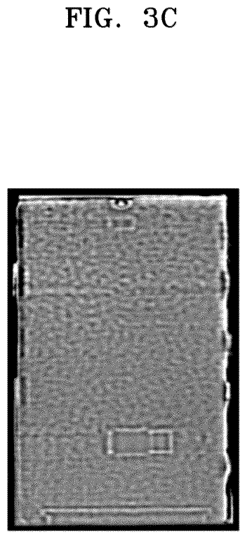

FIGS. 3A, 3B, and 3C are diagrams illustrating images of an embodiment and comparative examples.

FIG. 3A and FIG. 3B show images of a structure in which two layers of adhesive layers including a hard adhesive layer and a soft adhesive layer are formed on the display panel 10, and FIG. 3C shows an image of a structure in which a single adhesive layer is formed on the display panel 10.

FIG. 3A shows an image of an embodiment in which a hard adhesive layer and a soft adhesive layer are sequentially formed on the display panel 10. FIG. 3B shows an image of a comparative example having a structure in which a soft adhesive layer and a hard adhesive layer are sequentially stacked on the display panel 10. The hard adhesive layer in FIG. 3A and FIG. 3B has a storage modulus of about 0.9 MPa at 25° C., and the soft adhesive layer in FIG. 3A and FIG. 3B has a storage modulus of about 0.1 MPa at 25° C.

FIG. 3C shows an image of a comparative example in which a single adhesive layer having a storage modulus of about 0.18 MPa at 25° C. is on the display panel 10.

Referring to FIG. 3A and FIG. 3B, compared to the comparative example of FIG. 3C in which a single adhesive layer is formed on the display panel 10, the surface quality was improved as waviness is improved in the embodiment of FIG. 3A and the comparative example of FIG. 3B in which a hard adhesive layer and a soft adhesive layer having different storage moduli from each other are formed together on the display panel 10.

The surface quality has improved due to improved waviness in the embodiment of FIG. 3A in which a hard adhesive layer and a soft adhesive layer are formed in that order on the display panel 10 compared to the comparative example of FIG. 3B in which a soft adhesive layer and a hard adhesive layer are formed in that order on the display panel 10.

TABLE 1

| | | | | | Ball |
|---|---|---|---|---|---|
| | | Thickness | G′(MPa) | | drop |
| | | (μm) | at 25 | Kc | (cm) |
| Embodiment 1 | upper adhesive | 100 | 0.1 | 0.17 | 4.4 |
| | layer | | | | |
| | lower adhesive | 25 | 0.9 | | |
| | layer | | | | |
| Embodiment 2 | upper adhesive | 75 | 0.1 | 0.15 | 5.1 |
| | layer | | | | |
| | lower adhesive | 50 | 0.9 | | |
| | layer | | | | |
| Comparative | upper adhesive | 50 | 0.1 | 0.13 | 3 |
| Example 1 | layer | | | | |
| | lower adhesive | 75 | 0.9 | | |
| | layer | | | | |
| Comparative | upper adhesive | 25 | 0.1 | 0.15 | 3.2 |
| Example 2 | layer | | | | |
| | lower adhesive | 100 | 0.9 | | |
| | layer | | | | |
| Comparative | upper adhesive | 25 | 0.9 | 0.22 | 5.1 |
| Example 3 | layer | | | | |
| | lower adhesive | 100 | 0.1 | | |
| | layer | | | | |
| Comparative | upper adhesive | 50 | 0.9 | 0.25 | 3.3 |
| Example 4 | layer | | | | |
| | lower adhesive | 75 | 0.1 | | |
| | layer | | | | |

G′: storage modulus
Kc: curvature

Table 1 shows curvature Kc, which is an index of surface quality evaluation, and results of a ball drop test, which is one of impact resistance evaluations, of each embodiment and each comparative example. The lower the curvature Kc of a display device, the better the surface flatness and the better the surface quality. A value of the curvature Kc is a curvature parameter measured for waviness having a wavelength range of about 1.0 mm to about 3.0 mm formed on a display panel (for example, the surface of an upper layer of a display panel) by phase stepped deflectometry (PSD). In the specification, result values of a ball dropping test were measured at the highest height at which no dent occurs in case that a ball weighing about 0.5 g is dropped onto a display device. If the value of Kc is about 0.2 or less, the surface quality is determined to be good, and if a test result of the ball drop test is 4 or more, the impact resistance is determined to be good.

Embodiment 1, Embodiment 2, Comparative Example 1, and Comparative Example 2 each have a structure in which a hard adhesive layer is arranged relatively closer to the display panel 10 than a soft adhesive layer. For example, in Embodiment 1, Embodiment 2,Comparative Example 1, and Comparative Example 2, the lower adhesive layer is a hard adhesive layer with a storage modulus of about 0.9 MPa at about 25° C., and the upper adhesive layer is a soft adhesive layer having a storage modulus of about 0.1 MPa at about 25° C.

The thickness of the hard adhesive layer disposed in a relatively lower portion in Embodiment 1 and Embodiment 2 and Comparative Example 2 was smaller than the thickness of the soft adhesive layer disposed in a relatively upper portion. The thickness of the hard adhesive layer disposed in a relatively lower portion in Comparative Example 1 and Comparative Example 2 was greater than the thickness of the soft adhesive layer disposed in a relatively upper portion. In detail, in Embodiment 1, the thickness of the lower adhesive layer was about 25 μm, and the thickness of the upper adhesive layer was about 100 μm. In Embodiment 2, the thickness of the lower adhesive layer was about 50 μm, and the thickness of the upper adhesive layer was about 75 μm. In Comparative Example 1, the thickness of the lower adhesive layer was about 75 μm, and the thickness of the upper adhesive layer was about 50 μm. In Comparative Example 2, the thickness of the lower adhesive layer was about 100 μm, and the thickness of the upper adhesive layer was about 25 μm.

Comparative Embodiments 3 and 4 each have a structure in which the soft adhesive layer is arranged relatively closer to the display panel 10 than the hard adhesive layer. Comparative Example 3 and Comparative Example 4 have a structure in which only the vertical order of the arrangement of the soft adhesive layer and the hard adhesive layer of Embodiment 1 and Embodiment 2 is changed, respectively, and the thickness and storage modulus of the adhesive layers were the same. For example, in Comparative Embodiments 3 and 4, the lower adhesive layer is a soft adhesive layer with a storage modulus of about 0.1 MPa at about 25° C., and the upper adhesive layer is a hard adhesive layer with a storage modulus of about 0.9 MPa at about 25° C.

Referring to Table 1, in the case of Embodiment 1, Embodiment 2,Comparative Example 1, and Comparative Example 2 in which the hard adhesive layer is disposed in a relatively lower portion, the Kc value was about 0.2 or less and the surface quality was good, whereas in Comparative Example 3 and Comparative Example 4 in which the soft adhesive layer is disposed in a relatively lower portion, the Kc value exceeded about 0.2, and thus the surface quality was relatively deteriorated.

In Embodiment 1 and Embodiment 2, impact resistance was good as ball drop test results thereof show a value of about 4 cm or more. It can be seen that Comparative Example 1 and Comparative Example 2 have poor impact resistance as ball drop test results thereof show about 3 cm and about 3.2 cm, respectively.

Accordingly, in case that the thickness of the hard adhesive layer is greater than the thickness of the soft adhesive layer, the impact resistance deteriorates and the conditions of impact resistance and surface quality are not met at the same time.

Comparative Example 3 has good impact resistance with a ball drop test result of 5.1 cm or more, but as described above, the Kc value is less than about 0.2, and thus the conditions of impact resistance and surface quality are not met. In Comparative Example 4, the ball drop test result showed that the impact resistance was poor as about 3.3 cm, and thus it can be confirmed that both the impact resistance and surface quality conditions were poor.

Accordingly, it can be seen that the impact resistance and the surface quality have improved at the same time in embodiments in which the hard adhesive layer is disposed closer to the display panel 10 than the soft adhesive layer, unlike the comparative examples in which the soft adhesive layer is disposed closer to the display panel 10 than the hard adhesive layer.

TABLE 2

| | | G′ | G′ | G′at | G′at | G′at |
|---|---|---|---|---|---|---|
| | Ball | at 25° | at −20° | 1000 | 5000 | 10000 |
| | drop | C. | C. | Hz | Hz | Hz |
| | (cm) | (MPa) | (MPa) | (MPa) | (MPa) | (MPa) |
| Embodiment 3 | 7.6 | 0.04 | 0.15 | 0.12 | 0.34 | 0.74 |
| Embodiment 4 | 4.5 | 0.03 | 1.10 | 0.62 | 1.58 | 2.77 |
| Embodiment 5 | 4.3 | 0.31 | 1.70 | 1.14 | 2.09 | 2.45 |
| Embodiment 6 | 4.8 | 0.27 | 3.51 | 2.97 | 6.58 | 6.58 |
| Comparative | 3.3 | 0.10 | 77.2 | 2.22 | 9.97 | 14.45 |
| Example 5 | | | | | | |
| Comparative | 2.5 | 0.18 | 204 | 8.52 | 27.36 | 29.76 |
| Example 6 | | | | | | |

G′: storage modulus

Table 2 shows results of a ball drop test, which is one of impact resistance evaluations of each Embodiment and Comparative Example.

Referring to Table 2, Embodiments 3 to 6 have a storage modulus of 8 MPa or less in a high frequency range of about 1,000 Hz to about 10,000 Hz and a storage modulus of 5 MPa or less at −20° C. Comparative Examples 5 and 6 have a storage modulus of greater than 8 MPa in the high frequency range of about 1,000 Hz to about 10,000 Hz and a storage modulus of greater than 5 MPa at −20° C.

It can be confirmed that Embodiments 3 to 6 have good impact resistance as ball drop test results thereof show a value of 4 cm or more. On the other hand, it can be seen that Comparative Examples 5 and 6 have poor impact resistance as ball drop test results thereof show about 3.3 cm and about 2.5 cm, respectively.

Accordingly, in an embodiment, in case that the second adhesive layer 22 has a storage modulus of about 8 MPa or less in the high frequency range of about 1000 Hz to about 10000 Hz and a storage modulus of about 5 MPa or less at about −20° C., the impact resistance of the display device 1 may be further improved.

TABLE 3

| | | | G′ |
|---|---|---|---|
| | | E_{IT} | at 25° C. |
| | Kc | (MPa) | (MPa) |
| Embodiment 7 | 0.07 | 2.48 | 0.70 |
| Embodiment 8 | 0.17 | 1.23 | 0.90 |
| Comparative | 0.25 | 0.41 | 0.10 |
| Example 7 | | | |
| Comparative | 0.27 | 0.33 | 0.03 |
| Example 8 | | | |
| Comparative | 0.31 | 0.24 | 0.31 |
| Example 9 | | | |
| Comparative | 0.38 | 0.15 | 0.04 |
| Example 10 | | | |

G′: storage modulus
Kc: curvature
E_{IT}: indentation modulus

Table 3 shows the curvature Kc, which is an index of surface quality evaluation, for each Embodiment and Comparative Example. The indentation modulus (Eᵣᵣ) is the elastic modulus measured using a nanoindenter at room temperature.

Referring to Table 3, Embodiments 7 and 8 have indentation moduli of about 2.48 MPa and about 1.23 MPa, respectively. Comparative Example 7, Comparative Example 8,Comparative Example 9, and Comparative Example 10 have indentation moduli of about 0.41 MPa, about 0.33 MPa, about 0.24 MPa, and about 0.15 MPa, respectively.

From Table 3, it can be seen that the larger the indentation modulus, the lower the curvature of the display device. As Embodiments 7 and 8 have an indentation modulus of about 0.7 MPa or more, it can be confirmed that the quality is good in case that the Kc value is less than about 0.2. It can be seen that Comparative Examples 7 to 10 have an indentation modulus of less than about 0.7 MPa, and thus the quality deteriorates in case that the Kc value exceeds about 0.2.

Accordingly, in embodiment, in case that the first adhesive layer 21 has an indentation modulus of about 0.7 MPa or more, the surface quality of the display device 1 may be further improved.

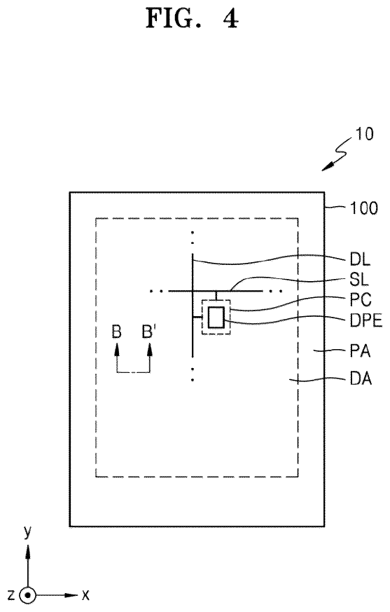

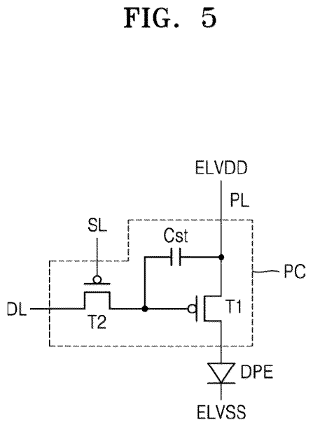

FIG. 4 is a schematic plan view schematically illustrating the display panel 10 included in the display device 1 according to an embodiment. FIG. 5 is an equivalent circuit diagram schematically illustrating a pixel circuit PC of the display panel 10 and a display element DPE connected to the pixel circuit PC. One display element DPE may correspond to one pixel. The display element DPE may be, for example, an organic light-emitting diode, an inorganic light-emitting diode, or a quantum dot light-emitting diode.

Referring to FIGS. 4 and 5, the display panel 10 may include a substrate 100, a pixel circuit PC, a scan line SL, a data line DL, a driving voltage line PL, and a display element DPE. As described above, the display device 1 may include the display panel 10, and the display panel 10 may include the substrate 100. For example, since the display device 1 may include the substrate 100, the substrate 100 may be regarded as having the display area DA and the peripheral area PA. Hereinafter, for convenience, the substrate 100 will be described as having a display area DA and a peripheral area PA.

The pixel circuit PC and the display element DPE may be arranged in the display area DA. As shown in FIG. 5, the pixel circuit PC may include a driving transistor T1, a switching transistor T2, and a storage capacitor Cst. The display element DPE may emit red, green, or blue light, or may emit red, green, blue, or white light.

The switching transistor T2 may be connected to the scan line SL and the data line DL, and may be configured to transmit, to the driving transistor T1, a data voltage or data signal input from the data line DL according to a scan voltage or scan signal input from the scan line SL.

The storage capacitor Cst may be connected to the switching transistor T2 and the driving voltage line PL, and may store a voltage corresponding to a difference between a voltage received from the switching transistor T2 and a first power supply voltage ELVDD supplied to the driving voltage line PL.

The driving transistor T1 may be connected to the driving voltage line PL and the storage capacitor Cst, and may control, in response to a voltage value stored in the storage capacitor Cst, a driving current flowing from the driving voltage line PL and through the display element DPE. The display element DPE may emit light with a given brightness by driving current. An opposite electrode (for example, cathode) of the display element DPE may receive a second power voltage ELVSS.

FIG. 5 illustrates the pixel circuit PC including two transistors and one storage capacitor, but the disclosure is not limited thereto. For example, the pixel circuit PC may include three or more transistors. For example, the pixel circuit PC may include two or more storage capacitors.

In the peripheral area PA, a scan driver (not shown) that provides a scan signal to the pixel circuit PC, a data driver (not shown) that provides a data signal to the pixel circuit PC, a power wiring (not shown) that provides the first power supply voltage ELVDD and/or the second power supply voltage to the pixel circuit PC may be arranged. A pad (not shown) may be arranged in the peripheral area PA, and a display circuit board may be electrically connected to the pad.

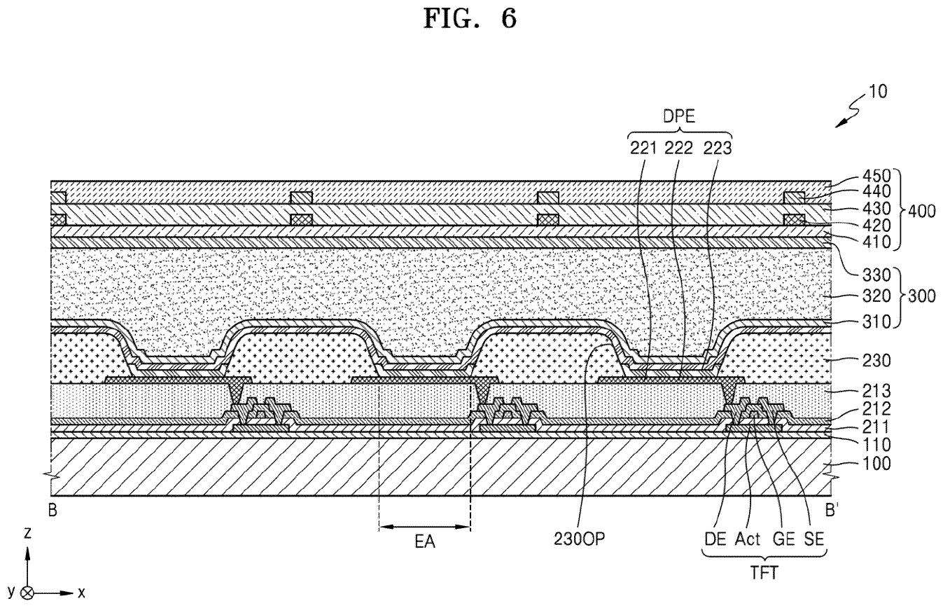

FIG. 6 is a schematic cross-sectional view schematically illustrating a cross-section taken along line B-B′ of the display panel 10 of FIG. 4.

Referring to FIG. 6, the display panel 10 may include the substrate 100, the transistor TFT, the display element DPE, an encapsulation layer 300, and a touch sensor layer 400.

The substrate 100 may include glass or a polymer resin. The substrate 100 may include a polymer resin such as polyethersulphone, polyacrylate, polyetherimide, polyethylene naphthalate, polyethylene terephthalate, polyphenylene sulfide, polyarylate, polyimide, polycarbonate, or cellulose acetate propionate. The substrate 100 may have flexible, rollable, or bendable characteristics. The substrate 100 may have a multilayer structure including a layer including the polymer resin described above and an inorganic layer (not shown).

The display element DPE and the transistor TFT electrically connected to the display element DPE may be disposed on the substrate 100. One display element DPE may correspond to one pixel.

Transistors TFT may be disposed on the substrate 100. The transistors TFT may be electrically connected to the display elements DPE, respectively. The transistors TFT respectively electrically connected to the display elements DPE may be each a transistor included in the pixel circuit PC described above with reference to FIGS. 4 and 5.

The buffer layer 110 may be located (or disposed) on the substrate 100 and reduce or block penetration of foreign substances, moisture, or external air from below the substrate 100. The buffer layer 110 may increase the smoothness of an upper surface of the substrate 100. The buffer layer 110 may be disposed between the substrate 100 and the transistor TFT. The buffer layer 110 may include an inorganic material such as an oxide or a nitride, an organic material or an organic-inorganic composite, and may have a single-layer or multi-layer structure of an inorganic material and an organic material. For example, the buffer layer 110 may include an inorganic material such as silicon oxide (SiOₓ), silicon nitride (SiNₓ), and/or silicon oxynitride (SiOₓN_{y}).

The transistor TFT may be disposed on the buffer layer 110. The transistor TFT may include a semiconductor layer Act, a gate electrode GE, a source electrode SE, and a drain electrode DE. FIG. 5 illustrates a top gate type transistor in which the gate electrode GE is disposed on the semiconductor layer Act with a gate insulating layer 211 therebetween, but the disclosure is not limited thereto. For example, the transistor TFT may be a bottom gate type.

The semiconductor layer Act may be located on the buffer layer 110. The semiconductor layer Act may include a channel region and a source region and a drain region doped with impurities on both sides of the channel region. The impurities may include N-type impurities or P-type impurities. The semiconductor layer Act may include amorphous silicon or polysilicon. In an embodiment, the semiconductor layer Act may include an oxide of at least one material selected from indium (In), gallium (Ga), stannum (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn). The semiconductor layer Act may be a Zn oxide-based material and may include Zn oxide, In—Zn oxide, Ga—In—Zn oxide, etc. Also, the semiconductor layer Act may include an In—Ga—Zn—O (IGZO), In—Sn—Zn—O (ITZO) or In—Ga—Sn—Zn—O (IGTZO) semiconductor including a metal such as such as indium (In), gallium (Ga), and tin (Sn).

The gate electrode GE may be disposed on the semiconductor layer Act such that at least a portion of the gate electrode GE overlaps the semiconductor layer Act. The gate electrode GE may overlap the channel region of the semiconductor layer Act. The gate electrode GE may include various conductive materials including molybdenum (Mo), aluminum (Al), copper (Cu), titanium (Ti), etc. and may have various layer structures. For example, the gate electrode GE may include a Mo layer and an Al layer, or may have a multilayer structure of Mo layer/Al layer/Mo layer. The gate electrode GE may have a multilayer structure including an ITO layer covering a metal material.

The gate insulating layer 211 between the semiconductor layer Act and the gate electrode GE may include an inorganic insulating material such as silicon oxide, silicon nitride, silicon oxy nitride, aluminum oxide, titanium oxide, tantalum oxide, and hafnium oxide. The gate insulating layer 211 may be a single layer or a multilayer including the above- described materials.

The source electrode SE and the drain electrode DE may be connected to the source and drain regions of the semiconductor layer Act through a contact hole. The source electrode SE and the drain electrode DE may include various conductive materials including molybdenum (Mo), aluminum (Al), copper (Cu), titanium (Ti), etc. and may have various layer structures. For example, the source electrode SE and the drain electrode DE may include a Ti layer and an Al layer, or may have a multilayer structure of Ti layer/Al layer/Ti layer. The source electrode SE and the drain electrode DE may have a multilayer structure including an ITO layer covering a metal material.

The interlayer insulating layer 212 may include an inorganic insulating material such as silicon oxide, silicon nitride, silicon oxy nitride, aluminum oxide, titanium oxide, tantalum oxide, and hafnium oxide. The interlayer insulating layer 212 may be a single layer or a multilayer including the above-described materials.

The gate insulating layer 211 and the interlayer insulating layer 212 each including an inorganic material may be formed through chemical vapor deposition (CVD) or atomic layer deposition (ALD), but are not limited thereto.

The transistor TFT may be covered with an organic insulating layer 213. For example, the organic insulating layer 213 may cover the source electrode SE and the drain electrode DE. The organic insulating layer 213 is a planarization insulating layer and may have a substantially flat upper surface. The organic insulating layer 213 may include an organic insulating material such as general-purpose polymers such as polymethylmethacrylate (PMMA) or polystyrene (PS), polymer derivatives with phenolic groups, acrylic polymers, imide polymers, aryl ether polymers, amide polymers, fluorine polymers, p-xylene-based polymers, vinyl alcohol-based polymers, and blends thereof. In an embodiment, the organic insulating layer 213 may include polyimide.

The display element DPE may be disposed on the organic insulating layer 213. The display element DPE may emit red, green, or blue light. The display element DPE may include, for example, a pixel electrode 221, an opposite electrode 223, and an intermediate layer 222 which is between the pixel electrode 221 and the opposite electrode 223 and may include an emission layer.

The pixel electrode 221 may be electrically connected to the transistor TFT by contacting either the source electrode SE or the drain electrode DE through a contact hole formed in the organic insulating layer 213. The pixel electrode 221 may include a conductive oxide such as indium tin oxide (ITO), indium zinc oxide (IZO), zinc oxide (ZnO), indium oxide (In₂O₃), indium gallium oxide (IGO) or aluminum zinc oxide (AZO). The pixel electrode 221 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or a compound thereof. For example, the pixel electrode 221 may have a structure having films formed of ITO, IZO, ZnO, or In₂O₃ above and below the above-described reflective layer. For example, the pixel electrode 221 may have a three-layer structure of ITO/Ag/ITO.

A pixel defining layer 230 may be disposed on the organic insulating layer 213. The pixel defining layer 230 may have an opening 230OP corresponding to each pixel. As the pixel defining layer 230 has the opening 230OP that exposes at least a central portion of the pixel electrode 221, the pixel defining layer 230 may have a function of defining a pixel. An emission area EA of the display element DPE may be defined by the opening 230OP of the pixel defining layer 230. At least a portion of the intermediate layer 222 may be located within (or in) the opening 230OP. The pixel defining layer 230 may increase a distance between an edge of the pixel electrode 221 and the opposite electrode 223 on the pixel electrode 221 to thereby perform a function of preventing arcs, etc. from occurring at the edge of the pixel electrode 221. The pixel defining layer 230 may include an organic material such as polyimide or hexamethyldisiloxane (HMDSO).

The intermediate layer 222 may include an emission layer. The emission layer may be disposed within (or in) the opening 230OP of the pixel defining layer 230. The emission layer may include a high-molecular material or a low-molecular material, and may emit red, green, blue, or white light. Additional functional layers may be selectively disposed below and above the emission layer, a hole transport layer (HTL), a hole injection layer (HIL), an electron transport layer (ETL), an electron injection layer (EIL), etc. The intermediate layer 222 may include a single layer across the pixel electrodes 221, or may include a layer patterned to correspond to each of the pixel electrodes 221. For example, the emission layer of the intermediate layer 222 may be patterned and disposed for each pixel, and a functional layer may be disposed across the pixel electrodes 221.

The opposite electrode 223 may be disposed on the intermediate layer 222. The opposite electrode 223 may be integral with the display elements DPE and correspond to the pixel electrodes 221. The opposite electrode 223 may be commonly provided in the display elements DPE. The opposite electrode 223 may include a conductive material with a relatively low work function. For example, the opposite electrode 223 may include a (semi-) transparent layer including silver (Ag), magnesium (Mg), aluminum (Al), nickel (Ni), chromium (Cr), lithium (Li), calcium (Ca), or alloys thereof. By way of example, the opposite electrode 223 may further include a layer such as ITO, IZO, ZnO or In₂O₃ on the (semi) transparent layer including the above-described material. In an embodiment, the opposite electrode 223 may include silver (Ag) and magnesium (Mg).

The encapsulation layer 300 may be disposed on the display element DPE. For example, the encapsulation layer 300 may be disposed on the opposite electrode 223. Since the display element DPE may be readily damaged by moisture or oxygen from the outside, the encapsulation layer 300 may cover the display element DPE to protect the display element DPE.

The encapsulation layer 300 may include at least one inorganic encapsulation layer and at least one organic encapsulation layer. In an embodiment, the encapsulation layer 300 may include first and second inorganic encapsulation layers 310 and 330 and an organic encapsulation layer 320 disposed therebetween.

The first and second inorganic encapsulation layers 310 and 330 may each include one or more inorganic insulating materials. The inorganic insulating material may include aluminum oxide (Al₂O₃), titanium oxide (TiO₂), tantalum oxide (Ta₂O₅), hafnium oxide (HfO₂), zinc oxide (ZnO), silicon oxide (SiOₓ), silicon nitride (SiNₓ), and/or silicon oxide. The first and second inorganic encapsulation layers 310 and 330 may be formed through CVD.

The organic encapsulation layer 320 may further include polyethylene terephthalate, polyethylene naphthalate, polycarbonate, polyimide, polyethylene sulfonate, polyoxymethylene, polyarylate, HMDSO, acrylic resin, or a combination thereof.

The touch sensor layer 400 may be disposed on the encapsulation layer 300. The touch sensor layer 400 may be disposed on the second inorganic encapsulation layer 330. The touch sensor layer 400 may obtain coordinate information according to an external input, for example, a touch event of an object such as a finger or a stylus pen.

The touch sensor layer 400 may include touch conductive patterns and touch insulating layers. For example, the touch sensor layer 400 may include a first touch insulating layer 410, a first touch conductive pattern 420, a second touch insulating layer 430, a second touch conductive pattern 440, and a third touch insulating layer 450. In an embodiment, the first touch insulating layer 410 may be a single layer or a multilayer including an inorganic material such as silicon nitride (SiNₓ), silicon oxide (SiOₓ), and/or silicon oxynitride (SiOₓN_{y}). In an embodiment, the first touch insulating layer 410 may include an organic material. In an embodiment, the first touch insulating layer 410 may be omitted.

The first touch conductive pattern 420 may be disposed on the first touch insulating layer 410 and/or the second inorganic encapsulation layer 330. In an embodiment, the first touch conductive pattern 420 may overlap the pixel defining layer 230. The first touch conductive pattern 420 may not overlap the openings of the pixel defining layer 230. The first touch conductive pattern 420 may include a conductive material. For example, the first touch conductive pattern 420 may contain molybdenum (Mo), aluminum (Al), copper (Cu), titanium (Ti), etc., and may be formed as a multilayer or single layer including the above materials. In an embodiment, the first touch conductive pattern 420 may have a structure (Ti/Al/Ti) in which a titanium layer, an aluminum layer, and a titanium layer are sequentially stacked, respectively.

The second touch insulating layer 430 may cover the first touch conductive pattern 420. The second touch insulating layer 430 may be a single layer or a multilayer including an inorganic material such as silicon nitride (SiNₓ), silicon oxide (SiOₓ), and/or silicon oxynitride (SiOₓN_{y}). In an embodiment, the second touch insulating layer 430 may include an organic material.

The second touch conductive pattern 440 may be disposed on the second touch insulating layer 430. In an embodiment, the second touch conductive pattern 440 may overlap the pixel defining layer 230. The second touch conductive pattern 440 may not overlap openings of the pixel defining layer 230. In an embodiment, the second touch conductive pattern 440 may be connected to the first touch conductive pattern 420 through a contact hole provided in the second touch insulating layer 430. The second touch conductive pattern 440 may include a conductive material. For example, the second touch conductive pattern 440 may include molybdenum (Mo), aluminum (Al), copper (Cu), titanium (Ti), etc., and may be formed as a multilayer or single layer including the above materials. In an embodiment, the second touch conductive pattern 440 may have a structure (Ti/Al/Ti) in which a titanium layer, an aluminum layer, and a titanium layer are sequentially stacked.

The first touch conductive pattern 420 and the second touch conductive pattern 440 may include touch sensing electrodes (not shown) for detecting a touch input. In an embodiment, touch sensing electrodes may sense an input using a mutual capacitance method. In an embodiment, touch sensing electrodes may sense an input using a self-capacitance method.

The third touch insulating layer 450 may cover the second touch conductive pattern 440. In an embodiment, the third touch insulating layer 450 may be a single layer or multilayer including an inorganic material such as silicon nitride (SiNₓ), silicon oxide (SiOₓ), and/or silicon oxynitride (SiOₓN_{y}). In an embodiment, the third touch insulating layer 450 may include an organic material.

The display device according to the embodiment may be applied to various electronic devices. An electronic device according to an embodiment of the present disclosure may include the display device (e.g., the display device of FIG. 1) described above, and may further include modules or apparatuses having additional functions in addition to the display device.

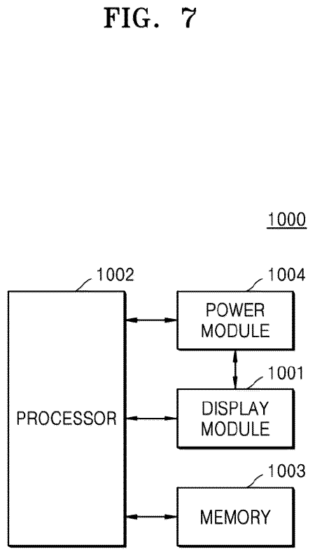

FIG. 7 is a block diagram of an electronic device according to an embodiment.

Referring to FIG. 7, an electronic device 1000 according to an embodiment may include a display module 1001, a processor 1002, a memory 1003, and a power module 1004.

The processor 1002 may include at least one of a central processing unit (CPU), an application processor (AP), a graphic processing unit (GPU), a communication processor (CP), an image signal processor (ISP), and a controller.

The memory 1003 may store data information necessary for the operation of the processor 1002 or the display module 1001. When the processor 1002 executes an application stored in the memory 1003, an image data signal and/or an input control signal may be transmitted to the display module 1001, and the display module 1001 may process a signal received and output image information through a display screen.

The power module 1004 may include a power supply module such as a power adapter or a battery device, and a power conversion module that converts the power supplied by the power supply module to generate power necessary for the operation of the electronic device 1000.

At least one of the components of the electronic device 1000 described above may be included in the display device according to the embodiments described above. In addition, a part among the individual modules functionally included in one module may be included in the display device, and another part may be provided separately from the display device. For example, the display device may include the display module 1001, and the processor 1002, the memory 1003, and the power module 1004 may be provided in the form of other devices within the electronic device 1000 except for the display device.

In an embodiment, the display module 1001 included in the display device may drive based on the image data signal and the input control signal received from the processor 1002.

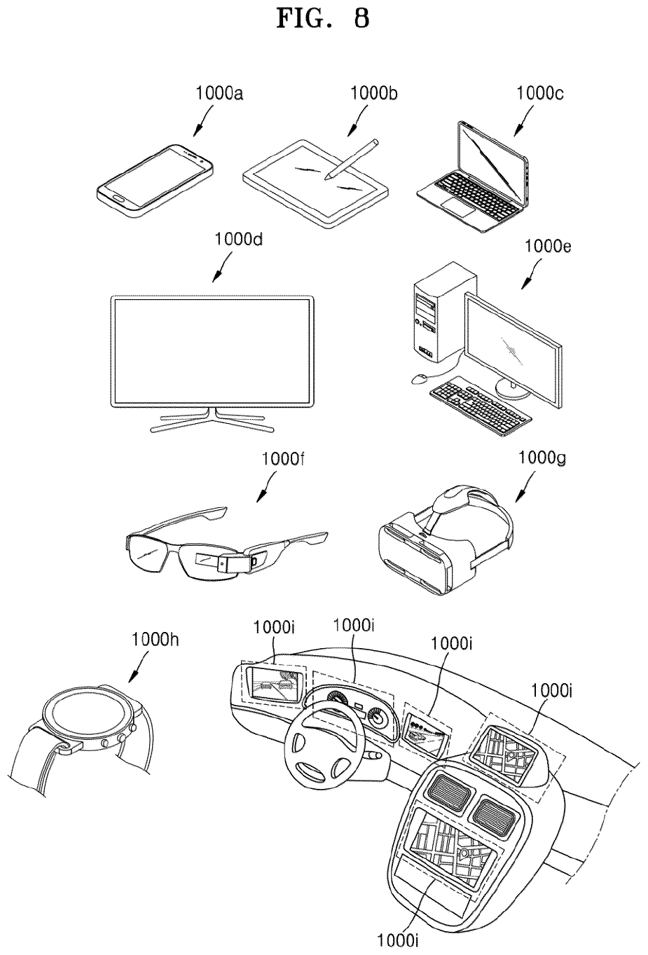

FIG. 8 is schematic diagrams of electronic devices according to various embodiments.

Referring to FIG. 8, various electronic devices to which display devices according to embodiments are applied may include not only image display electronic devices such as a smart phone 1000a, a tablet PC 1000b, a laptop 1000c, a TV 1000d, and a desk monitor 1000e, but also a wearable electronic device including display modules such as smart glasses 1000f, a head mounted display 1000g, and a smart watch 1000h, and a vehicle electronic device 1000i including a dashboard, a center fascia, and display modules such as a CID (Center Information Display) and a room mirror display disposed in the dashboard.

The disclosure has been described with reference to the embodiments shown in the drawings, but these are examples, and various modifications and other equivalent embodiments are possible therefrom by those of ordinary skill in the art. Therefore, the technical scope of protection of the disclosure should also be determined by the technical spirit of the appended claims.

According to embodiment, a display device with improved impact resistance and surface quality may be implemented by providing an adhesive member including a first adhesive layer and a second adhesive layer having different storage moduli from each other. The above-described effects are examples, and the scope of the disclosure is not limited by these effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope and as defined by the following claims.

What is claimed is:

1. A display device comprising:
a display panel;
a cover window disposed above the display panel; and
an adhesive member disposed between the display panel and the cover window, the adhesive member comprising a first adhesive layer and a second adhesive layer disposed between the first adhesive layer and the cover window, wherein
a storage modulus of the first adhesive layer is greater than a storage modulus of the second adhesive layer, and
an indentation modulus of the first adhesive layer is in a range of about 0.7 MPa to about 15 MPa.

2. The display device of claim 1, wherein the storage modulus of the second adhesive layer is in a range of about 0.001 MPa to about 5 MPa at about −20° C. or lower.

3. The display device of claim 1, wherein the storage modulus of the second adhesive layer is in a range of about 0.001 MPa to about 8 MPa in a high frequency range of about 1,000 Hz to about 10,000 Hz.

4. The display device of claim 1, wherein the storage modulus of the first adhesive layer is in a range of about 0.5 MPa to about 1.5 MPa at about 25° C.

5. The display device of claim 1, wherein the storage modulus of the second adhesive layer is in a range of about 0.02 MPa to about 0.5 MPa at about 25° C.

6. The display device of claim 1, wherein a thickness of the first adhesive layer is less than a thickness of the second adhesive layer.

7. The display device of claim 6, wherein the thickness of the first adhesive layer is in a range of about 25 μm to about 75 μm.

8. The display device of claim 6, wherein the thickness of the second adhesive layer is in a range of about 75 μm to about 100 μm.

9. The display device of claim 1, wherein the first adhesive layer comprises an acrylic adhesive, an acrylate-based adhesive, a urethane acrylate-based adhesive, or a rubber adhesive.

10. The display device of claim 1, wherein the second adhesive layer comprises a urethane-based adhesive, an acrylic adhesive, or a urethane acrylate-based adhesive.

11. The display device of claim 1, further comprising:
a protection member disposed below the display panel.

12. A display device comprising:
a display panel;
a cover window disposed above the display panel; and
an adhesive member disposed between the display panel and the cover window, the adhesive member comprising a first adhesive layer and a second adhesive layer disposed between the first adhesive layer and the cover window, wherein
a storage modulus of the first adhesive layer is greater than a storage modulus of the second adhesive layer, and
the storage modulus of the second adhesive layer is in a range of about 0.001 MPa to about 5 MPa at about −20° C. or lower.

13. The display device of claim 12, wherein the storage modulus of the second adhesive layer is in a range of about 0.001 MPa to about 8 MPa in a high frequency range of about 1,000 Hz to about 10,000 Hz.

14. The display device of claim 12, wherein the storage modulus of the first adhesive layer is in a range of about 0.5 MPa to about 1.5 MPa at about 25° C.

15. The display device of claim 12, wherein the storage modulus of the second adhesive layer is in a range of about 0.02 MPa to about 0.5 MPa at about 25° C.

16. The display device of claim 12, wherein a thickness of the first adhesive layer is less than a thickness of the second adhesive layer.

17. The display device of claim 16, wherein the thickness of the first adhesive layer is in a range of about 25 μm to about 75 μm.

18. The display device of claim 16, wherein the thickness of the second adhesive layer is in a range of about 75 μm to about 100 μm.

19. The display device of claim 12, wherein the first adhesive layer comprises an acrylic adhesive, an acrylate-based adhesive, a urethane acrylate-based adhesive, or a rubber adhesive.

20. The display device of claim 12, wherein the second adhesive layer comprises a urethane-based adhesive, an acrylic adhesive, or a urethane acrylate-based adhesive.

21. An electronic device comprising:
a display device, wherein the display device comprises:
a display panel;
a cover window disposed above the display panel; and
an adhesive member disposed between the display panel and the cover window, the adhesive member comprising a first adhesive layer and a second adhesive layer disposed between the first adhesive layer and the cover window,
a storage modulus of the first adhesive layer is greater than a storage modulus of the second adhesive layer, and
an indentation modulus of the first adhesive layer is in a range of about 0.7 MPa to about 15 MPa.

22. The electronic device of claim 21, further comprising:
a display module;
a processor; a power module; and
a memory,
wherein the display device includes one of the display module, the processor, the power module, or the memory.
